(19) United States
(12) Patent Application Publication
(10) Pub. No.: US 2013/0341782 A1
(43) Pub. Date: Dec. 26, 2013

(54) SEMICONDUCTOR PACKAGE MODULE

(71) Applicants: Kwang Soo Kim, Suwon (KR); Young Ki Lee, Suwon (KR); Bum Seok Suh, Suwon (KR)

(72) Inventors: Kwang Soo Kim, Suwon (KR); Young Ki Lee, Suwon (KR); Bum Seok Suh, Suwon (KR)

(73) Assignee: SAMSUNG ELECTRO-MECHANICS CO., LTD.

(21) Appl. No.: 13/614,112

(22) Filed: Sep. 13, 2012

(30) Foreign Application Priority Data
Jun. 25, 2012 (KR) 10-2012-0068102

(51) Int. Cl. H01L 23/367

(52) U.S. Cl. 257/706; 257/E23.102

(57) ABSTRACT

There is provided a semiconductor package module, and more particularly, a semiconductor package module constituted by modularizing power semiconductor devices incapable of being able to be easily integrated due to heat generated therefrom. To this end, the semiconductor package module includes a plurality of semiconductor packages; and a plurality of semiconductor packages; and a heat dissipation member having a pipe shape including a flow channel formed therein and including at least one or more through holes into which the semiconductor packages are inserted.

### CROSS-REFERENCE TO RELATED APPLICATIONS

This application claims the priority of Korean Patent Application No. 10-2012-0068102 filed on Jun. 25, 2012, in the Korean Intellectual Property Office, the disclosure of which is incorporated herein by reference.

### BACKGROUND OF THE INVENTION

1. Field of the Invention

The present invention relates to a semiconductor package module, and more particularly, to a semiconductor package module constituted by modularizing power semiconductor devices incapable of being easily integrated due to heat generated therefrom.

2. Description of the Related Art

Recently, demand for portable electronic products is remarkably increasing, and in order to satisfy the demand, the miniaturization and weight reduction of electronic components mounted in the portable electronic products are required.

Thus, when a semiconductor package is designed, a method of installing as many components and wirings as possible in a predetermined space therein, as well as a method of reducing the size of electronic components becomes more important.

A power semiconductor device generates a large amount of heat while being driven. Since such high-temperature heat affects the lifespan and operation of an electronic product, it is also important to overcome a heat problem in a semiconductor package.

To this end, a conventional power semiconductor package uses a structure in which both a power device and a control device are mounted on one surface of a circuit substrate, and a heat sink for emitting heat is disposed on the other surface thereof .

However, a conventional power semiconductor package may have the following problems.

Due to demand for miniaturized packages, the number of semiconductor devices disposed in a limited space is increased, and thus, a large amount of heat may be generated from an inside of a package. In this case, heat may not be effectively dissipated only via a heat sink disposed below the package.

In addition, a conventional semiconductor package module mainly has a structure in which a plurality of semiconductor packages are coupled to a single heat sink. Thus, conventionally, when an error arises in any one of a plurality of semiconductor packages constituting a semiconductor package module, since it is impossible to only replace the semiconductor package in which the error has arisen, the semiconductor package module itself needs to be replaced.

### RELATED ART DOCUMENT

(Patent Document 1) Korean Patent Laid-Open Publication No. 1998-0043254

### SUMMARY OF THE INVENTION

An aspect of the present invention provides a semiconductor package module having excellent heat dissipation properties.

Another aspect of the present invention provides a semiconductor package module in which semiconductor packages are individually replaced.

According to an aspect of the present invention, there is provided a semiconductor package module, including: a plurality of semiconductor packages; and a heat dissipation member having a pipe shape including a flow channel formed therein and including at least one or more through holes into which the semiconductor packages are inserted.

The semiconductor packages may each have a rectangular cross section, and may be inserted into the heat dissipation member so as to be arranged to be parallel to each other.

The heat dissipation member may include at least one protrusion protruding into the flow channel and guiding a flow of a refrigerant in the flow channel towards the semiconductor packages.

The protrusion maybe disposed in a space formed between the through holes that are adjacent to each other in the flow channel.

The semiconductor packages may be arranged to have diamond shapes in which corners thereof are adjacent to each other.

In the heat dissipation member, an overall path of the flow channel may have a diamond pattern shape in accordance with the arrangement of the semiconductor packages.

The semiconductor package module may further include a substrate connected with external connection terminals of the semiconductor packages.

The semiconductor package module may further include a bus bar electrically connected to all of common connection terminals among external connection terminals of the semiconductor packages.

Each of the semiconductor packages may include a common connection terminal having a flat plate shape; first and second electronic devices respectively bonded to two surfaces of the common connection terminal; first and second connection terminals each having a flat plate shape and bonded to the first electronic device; and a third connection terminal having a flat plate shape and bonded to the second electronic device.

The first electronic device may be a power semiconductor device, and the second electronic device may be a diode device.

The common connection terminal may be a collector terminal, the first connection terminal may be a gate terminal, the second connection terminal may be an emitter terminal, and the third connection terminal may be an anode terminal.

The common connection terminal, the first connection terminal, the second connection terminal, and the third connection terminal may be arranged to be parallel to each other.

The first connection terminal, the second connection terminal, and the third connection terminal may protrude toward one surface of each semiconductor package, and the common connection terminal may protrude toward the other surface thereof.

The semiconductor package module may further include a base substrate for dissipating heat, disposed in at least one side of an exterior of the first, second, and third connection terminals.

The semiconductor packages may be respectively formed in such a manner that at least one surface of the base substrate is coupled to the heat dissipation member so as to surface-contact the heat dissipation member.

The semiconductor package module may further include a molding part for sealing the first and second electronic devices therein.

The heat dissipation member may further include at least one support protrusion for supporting the semiconductor packages, the support protrusion being formed at either opening of both ends of the through holes.

According to another aspect of the present invention, there is provided a semiconductor package module, including: a heat dissipation member including a flow channel formed therein, the flow channel having a refrigerant flowing therein; and at least one or more semiconductor packages detachably inserted into the heat dissipation member, wherein the semiconductor packages each have at least four surfaces surface-contacting the heat dissipation member.

The semiconductor packages may be arranged in such a manner that corners thereof are adjacent to each other and an overall path of the flow channel has a diamond pattern.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view of a semiconductor package module according to an embodiment of the present invention;

FIG. 2 is a schematic perspective view of a semiconductor package shown in FIG. 1;

FIG. 3 is a penetrating perspective view of the semiconductor package shown in FIG. 2;

FIG. 4 is a cross-sectional view of the semiconductor package taken along line A-A′ of FIG. 2;

FIG. 5 is a cross-sectional view of the semiconductor package module taken along line A-B of FIG. 1;

FIG. 6 is a cross-sectional view of the semiconductor package module taken along line C-D of FIG. 1;

FIG. 7 is an exploded perspective view of the semiconductor package module of FIG. 1;

FIG. 8 is a schematic cross-sectional view of a semiconductor package module according to another embodiment of the present invention; and

FIG. 9 is a graph illustrating a relationship between a pressure reduction in a flow channel of the semiconductor package module according to the embodiment of the present invention and heat dissipation efficiency.

### DETAILED DESCRIPTION OF THE INVENTION

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

Hereinafter, embodiments of the present invention will be described in detail with reference to the accompanying drawings.

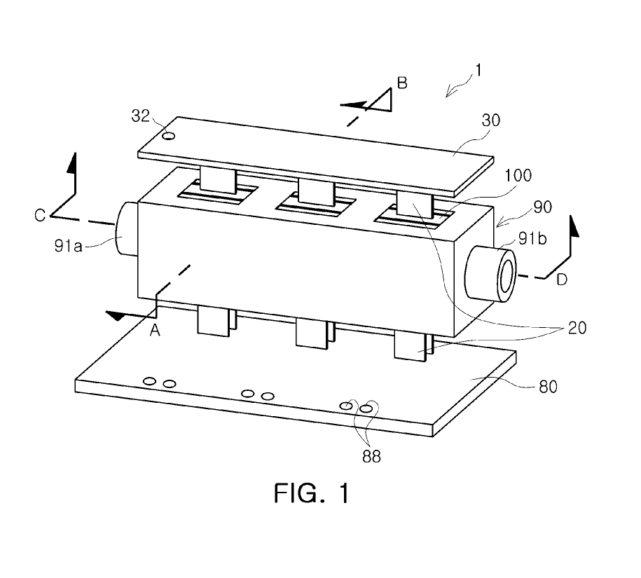

FIG. 1 is a schematic perspective view of a semiconductor package module according to an embodiment of the present invention.

Referring to FIG. 1, a semiconductor package module 1 according to the present embodiment may include at least one semiconductor package 100, a heat dissipation member 90, substrates 80, and a bus bar 30.

The semiconductor package 100 may be a power semiconductor package including a power semiconductor device to provide power.

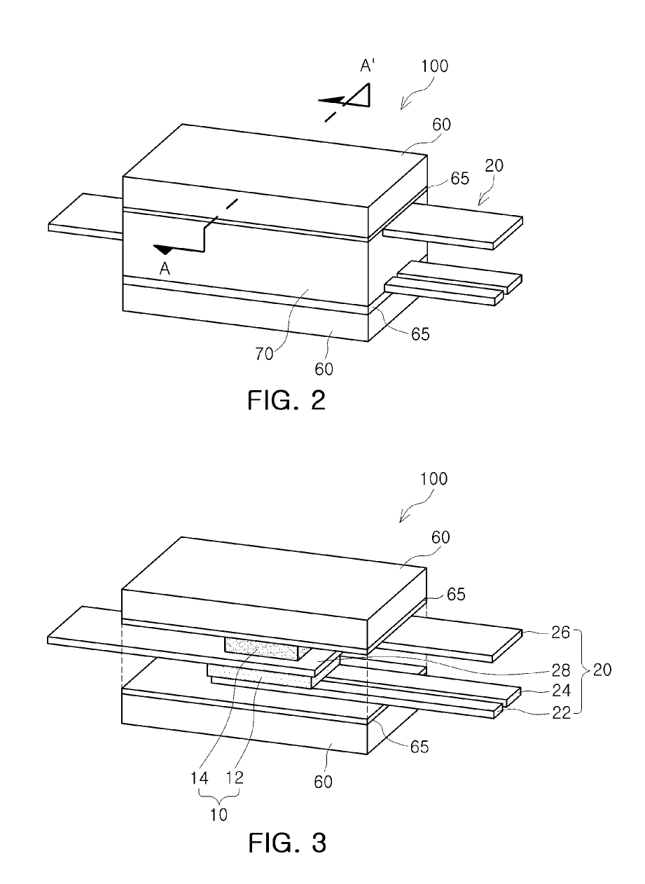

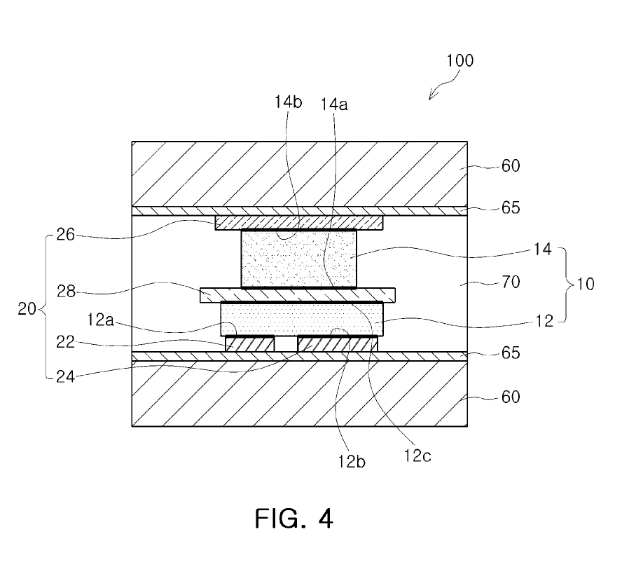

FIG. 2 is a schematic perspective view of the semiconductor package shown in FIG. 1. FIG. 3 is a penetrating perspective view of the semiconductor package shown in FIG. 2. FIG. 4 is a cross-sectional view of the semiconductor package 100 taken along line A-A′ of FIG. 2.

Referring to FIGS. 2 through 4, the semiconductor package 100 according to the present embodiment may include an electronic device 10, an external connection terminal 20, abase substrate 60, and a molding part 70.

The electronic device 10 may include various devices such as a passive device, an active device, and the like. In particular, the electronic device 10 according to the present embodiment may include a first electronic device 12 (e.g., a power semiconductor device) and a second electronic device 14 (e.g., a diode device). In this case, the first electronic device 12 as a power semiconductor device (hereinafter, referred to as “a power semiconductor device 12”) may be an insulated-gate bipolar transistor (IGBT) and the second electronic device 14 as a diode (hereinafter, referred to as “a diode device 14”) may be a fast recovery diode (FRD).

That is, the semiconductor package 100 according to the present embodiment may be a power semiconductor package including the power semiconductor device 12 and the diode device 14 connected between a current input electrode and a current output electrode of the power semiconductor device 12. However, the present invention is not limited thereto.

In addition, a plurality of electrodes may be formed on the respective power semiconductor device and diode device of the electronic device 10 according to the present embodiment.

In detail, a gate electrode 12a and an emitter electrode 12b may be formed on one surface of the power semiconductor device 12 and a collector electrode 12c may be formed on the other surface of the power semiconductor device 12. In addition, a cathode electrode 14a may be formed on a surface of the diode device 14 and an anode electrode 14b maybe formed on the other surface of the diode device 14.

In particular, the power semiconductor device and diode device of the electronic device 10 according to the present embodiment are stacked on each other. That is, in the semiconductor package 100 according to the present embodiment, the power semiconductor device 12 and the diode device 14 of the electronic device 10 may be stacked on each other in such a manner that a surface of the diode device 14 faces the other surface of the power semiconductor device 12, rather than being disposed on the same plane.

In this case, the power semiconductor device 12 and the diode device 14 are respectively coupled to two surfaces of a common connection terminal 28, a collector connection terminal, to be stacked each other.

The external connection terminal 20 may include a plurality of external connection terminals each formed of a flat metal plate. Thus, the plurality of external connection terminals 20 according to the present embodiment may surface-contact two surfaces of the power semiconductor device 12 and the diode device 14 of the electronic device 10 and may be bonded to the electrodes 12a to 12c and 14a to 14b of the electronic device 10.

The external connection terminals 20 according to the present embodiment may be first, second, and third connection terminals 22, 24, and 26 that are separate connection terminals, and the common connection terminal 28. In this case, the first connection terminal 22 may be a gate connection terminal that is connected to the gate electrode 12a. The second connection terminal 24 may be an emitter connection terminal connected to the emitter electrode 12b. The third connection terminal 26 may be an anode connection terminal connected to the anode electrode 14b. In addition, the common connection terminal 28 may be a collector connection terminal connected to the collector electrode 12c.

One surface of the common connection terminal 28 is bonded to the collector electrode 12c of the power semiconductor device 12. The other surface of the common connection terminal 28 is bonded to the cathode electrode 14a of the diode device 14. That is, the common connection terminal 28 is interposed and bonded between the power semiconductor device 12 and the diode device 14.

Thus, the collector electrode 12c of the power semiconductor device 12 and the cathode electrode 14a of the diode device 14 may be electrically connected to each other via the common connection terminal 28, and may share the common connection terminal 28 to be electrically connected to an external device.

The external connection terminals 20 each have a flat plate shape and may be arranged to be parallel to each other. In addition, as shown in FIG. 3, the present embodiment illustrates a case in which the common connection terminal 28 and the first, second, and third connection terminals 22, 24, and 26 are arranged to protrude in different directions (e.g., opposite directions). However, the present invention is not limited thereto. For example, the common connection terminal 28 and the first, second, and third connection terminals 22, 24, and 26 may protrude in the same direction. Likewise, the common connection terminal 28 and the first, second, and third connection terminals 22, 24, and 26 each having a flat plate shape maybe arranged in the various forms if necessary as long as they may surface-contact the power semiconductor device 12 and the diode device 14 of the electronic device 10, to be boned thereto.

The external connection terminal 20 may be formed of, but is not limited to, a material, such as copper (Cu), aluminum (Al), or the like.

The base substrate 60 is disposed in at least one side of the outside of the first, second, and third connection terminals 22, 24, and 26 and dissipates heat generated from the electronic device 10 outwardly.

The base substrate 60 may be formed of a metal material in order to effectively dissipate heat to the outside. In this case, the base substrate 60 may be formed of Al or an Al alloy, which is relatively inexpensive, is easily used, and also has excellent thermal conductivity. However, the present invention is not limited thereto. The base substrate 60 may be formed of various kinds of material having excellent thermal conductivity, such as graphite or the like, other than metal.

In the semiconductor package 100 according to the present embodiment, in order to prevent short circuits due to electrical connections between the base substrate 60 and the external connection terminals 20, an insulating layer 65 may be interposed between the base substrate 60 and the external connection terminals 20.

The insulating layer 65 may be formed of various kinds of material, as long as the material may have high thermal conductivity, allow for firmly bonding and fixing of the base substrate 60 and the external connection terminals 20, and electrically insulate the base substrates 60 and the external connection terminals 20 from each other. For example, the insulating layer 65 maybe formed of an insulating adhesive such as an epoxy resin or the like. However, the present invention is not limited thereto.

The molding part 70 is formed to partially cover and seal the electronic device 10 and the external connection terminals 20 bonded to the electronic device 10 to protect the electronic device 10 from an external environment. In addition, the molding part 70 may surround an outer surface of the electronic device 10 and fix the electronic device 10 therein to thereby stably protect the electronic device 10 from external impacts.

The present embodiment illustrates a case in which the base substrate 60 is attached to an exterior of the molding part 70. In this case, five surfaces of the base substrate 60 is exposed to the outside, thereby allowing for an increase in a heat dissipation effect.

However, the present invention is not limited thereto. For example, a part of the base substrate 60 may be covered by the molding part 70. In this case, at least one surface of each of the base substrates 60 maybe exposed out of the molding part 70.

Due to this structure, the semiconductor package 100 according to the present embodiment is formed to have a substantially rectangular parallelepiped shape by the base substrate 60 and the molding part 70, and the substrates 80 for dissipating heat may be disposed on at least two surfaces of the semiconductor package 100 having a rectangular parallelepiped shape and exposed to the outside.

The molding part 70 may be formed of an insulating material. In particular, the molding part 70 may be formed of a material having high thermal conductivity, such as silicone gel, thermally-conductive epoxy, ployimide, or the like.

Referring back to FIG. 1, the heat dissipation member 90 according to the present embodiment may contact an outer surface of the semiconductor package 100, absorb heat generated from the semiconductor package 100, and then, dissipate the heat to the outside.

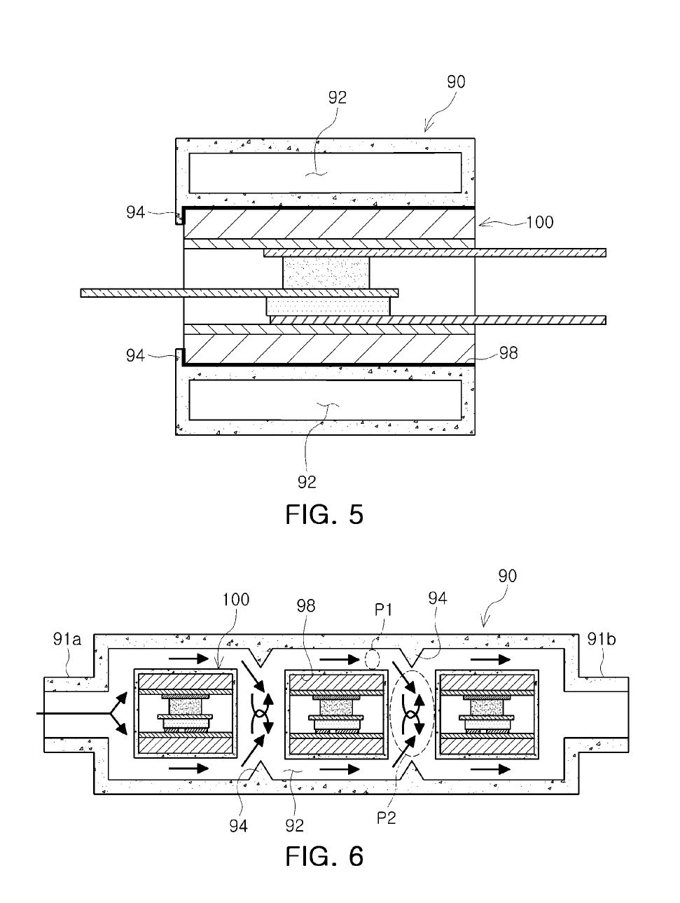

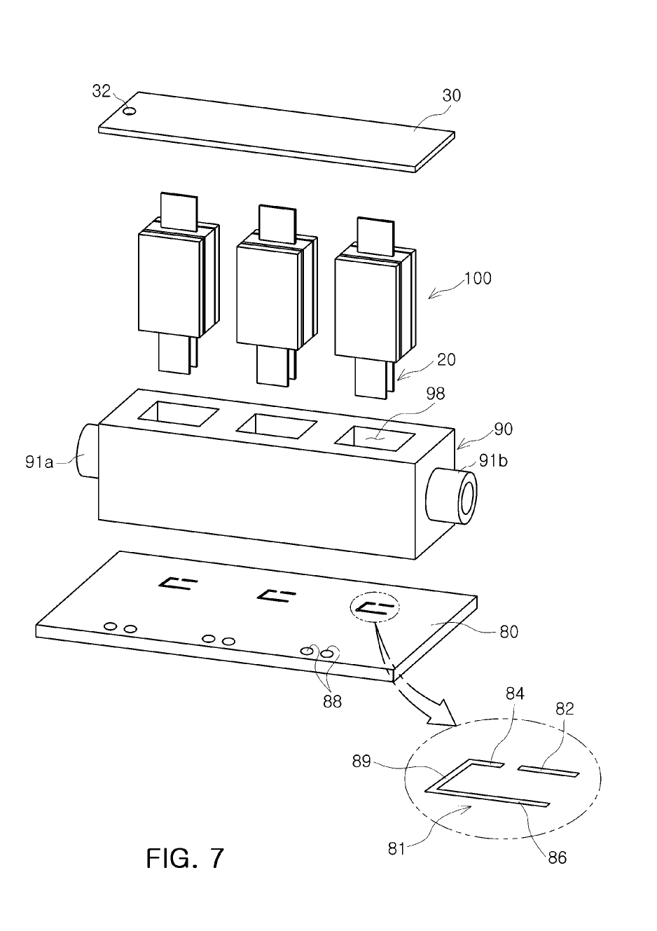

FIG. 5 is a cross-sectional view of the semiconductor package module taken along line A-B of FIG. 1. FIG. 6 is a cross-sectional view of the semiconductor package module taken along line C-D of FIG. 1, in which the bus bar 30 and the substrate 80 are not shown. In addition, FIG. 7 is an exploded perspective view of the semiconductor package module 1 of FIG. 1.

Referring to FIGS. 5 through 7, the heat dissipation member 90 according to the present embodiment may include a pipe shaped housing forming an external wall, at least one through hole 98 formed in the housing, and an inlet 91a and an outlet 91b through which a refrigerant is introduced and discharged.

The semiconductor package 100 is inserted into the through hole 98 to be coupled to the heat dissipation member 90.

The through hole 98 is formed to completely penetrate the housing of the heat dissipation member 90 and may be a hole having a shape corresponding to the shape of the semiconductor package 100. According to the present embodiment, the semiconductor package 100 has a rectangular parallelepiped shape overall. Accordingly, the through hole 98 may be a hole having a rectangular cross section.

In addition, the heat dissipation member 90 may include a support protrusion 94 that is formed at either opening of both ends of the through hole 98. The support protrusion 94 may be provided to prevent the semiconductor package 100 inserted into the through hole 98 from being escaped from the through hole 98.

Thus, the semiconductor package 100 is fixed into the through hole 98 in such a manner that the semiconductor package 100 is inserted through one end of the through hole 98 and does not escaped from the other end of the through hole 98 by the support protrusion 94 formed at the other end of the through hole 98.

As described above, the housing of the heat dissipation member 90 may have a pipe shape. Thus, a void is formed in the housing and is used as a flow channel 92 through which a refrigerant flows.

That is, the heat dissipation member 90 according to the present embodiment may be a heat dissipation device for dissipating heat of the semiconductor package 100 by using the refrigerant. In this case, example of the refrigerant may include liquid such as water, or gas.

To this end, the heat dissipation member 90 according to the present embodiment may include the inlet 91a through which the refrigerant is introduced to the flow channel 92, and the outlet 91b through which the refrigerant has absorb heat while passing through the heat dissipation member 90 is discharged from the heat dissipation member 90.

According to the present embodiment, the inlet 91a and the outlet 91b are disposed at either end of the housing. However, the present invention is not limited thereto. If necessary, the inlet 91a and the outlet 91b may be disposed at various positions.

In addition, in the heat dissipation member 90 according to the present embodiment, at least one protrusion 94 may be formed in the flow channel 92 in order to increase a heat dissipation effect.

As shown in FIG. 6, the protrusion 94 protrudes into the flow channel 92 and guides a flow of a refrigerant along the flow channel 92 toward the semiconductor package 100.

The protrusion 94 is disposed in a space formed between through holes 98. A flow direction of the refrigerant in the flow channel 92 is changed by the protrusion 94. A path may be formed such the refrigerant may contact a side wall of the through hole 98 due to the protrusion 94 for as long period of time as possible. Thus, the refrigerant may absorb as much amount of heat as possible when transferring in the flow channel 92.

According to the present embodiment, the semiconductor package module 1 having the above-described embodiment may normally operate when the anode electrode 14b of the diode device 14 is electrically connected to the emitter electrode 12b of the power semiconductor device 12.

To this end, a structure for electrically connecting the anode electrode 14b and the emitter electrode 12b to each other is further included in the semiconductor package 100 according to the related art.

However, in the semiconductor package 100 according to the present embodiment, the anode electrode 14b and the emitter electrode 12b are not connected to each other in the package 100, while the anode electrode 14b and the emitter electrode 12b are connected to each other on the substrate 80 on which the semiconductor package 100 is mounted.

As shown in FIG. 7, the substrate 80 having the semiconductor package 100 mounted thereon maybe provided with a plurality of electrode pads 81 to which respective external connection terminals 20 are bonded. In detail, the electrode pads 81 may include first, second, and third electrode pads 82, 84, and 86, and a connection pattern 89.

According to the present embodiment, the first electrode pad 82 may be a gate electrode pad to which a gate connection terminal 22 that is the first connection terminal 22 is bonded, the second electrode pad 84 may be an emitter electrode pad to which an emitter connection terminal that is the second connection terminal 24 is bonded, and the third electrode pattern 86 may be an anode electrode pad to which an anode connection terminal that is the third connection terminal 26 is bonded.

In addition, according to the present embodiment, the electrode pads 81 may include the connection pattern 89 for electrically connecting the second electrode pad 84 and the third electrode pattern 86, that is, the emitter electrode pad and the anode electrode pad, to each other.

Thus, when the semiconductor package 100 is mounted on the substrate 80, the second connection terminal 24, that is, the emitter connection terminal and the third connection terminal 26, that is, the anode connection terminal, of the semiconductor package 100 are electrically connected to each other by the connection pattern 89 of the substrate 80, thereby completely forming an overall circuit of the semiconductor package 100.

Thus, the semiconductor package 100 according to the present embodiment is mounted on the substrate 80 to be normally operated.

According to the present embodiment, the connection pattern 89 is formed on one surface of the substrate 80. However, the present invention is not limited thereto. That is, various applications maybe used in the present invention. For example, a connection pattern may be formed through wiring patterns formed in multilayered substrates or maybe formed on the other surface of the substrate 80.

The present embodiment illustrates a case in which respective external connection terminals 20 are bonded to the electrode pads 81 of the substrate 80, and the semiconductor package 100 is mounted on the substrate 80. In this case, the external connection terminals 20 maybe bonded to the electrode pads 81 via a solder or the like.

The present invention is not limited to the above-described structure and various applications maybe used therein.

For example, the connection pattern 89 of the substrate 80 may be omitted, and the emitter connection terminal as the second connection terminal 24 and the anode connection terminal as the third connection terminal 26 may be electrically connected to each other by using a separate connecting member (e.g., a conductive wire, a clamp, or the like).

A plurality of coupling holes 88 for coupling an external wire (not shown) thereto may be formed in an edge surface of the substrate 80.

Thus, the coupling holes 88 may be electrically connected to the electrode pads 81 via wirings pattern of the substrate 80. The semiconductor package 100 may be provided in plural and respective packages 100 may be electrically connected to an external device (e.g., an inverter system) via an external wire coupled to the coupling holes 88.

If necessary, the coupling holes 88 may be formed in various positions and may be formed in various amounts.

A bus bar 30 is electrically connected to the common connection terminal 28 of the semiconductor package 100. In the semiconductor package 100 according to the present embodiment, the common connection terminal 28 protrudes in a direction opposing to a direction in which the remaining external connection terminals 20, that is, the first, second, and third connection terminals 22, 24, and 26 protrude, such that the bus bar 30 is also disposed at an opposite side of the substrate 80.

The bus bar 30 may have a flat bar shape formed of a metal material. At least one coupling hole 32 for coupling an external device (e.g., a housing of an inverter system) thereto or connecting an external wire therewith may be formed in one end of the bus bar 30. When the bus bar 30 is coupled to an external device, the bus bar 30 may be electrically connected to an external device (e.g., an inverter system).

In the semiconductor package 100 having the above-described structure according to the present embodiment, the external connection terminal 20 having a plate shape may surface-contact an electrode of the electronic device 10 to be bonded thereto without a bonding wire. Thus, as compared with a semiconductor package according to the related art, bonding reliability may be ensured and a bonding wire may barely be deformed during the formation of the molding part 70, thereby significantly reducing defects occurring in a manufacturing process in the semiconductor package 100 according to the embodiment of the present invention.

In addition, unlike a semiconductor package according to the related art, the semiconductor package 100 according to the present embodiment may not include a separate component for electrically connecting the emitter connection terminal as the second connection terminal 24 and the anode connection terminal as the third connection terminal 26 and may be manufactured by repeatedly stacking the first and second devices included in the electronic device 10 and the external connection terminals 20. Thus, as compared with a semiconductor package according to the related art, the semiconductor package 100 according to the present embodiment may be easily manufactured and the manufacturing time and costs required for the semiconductor package 100 may be minimized.

In addition, a two-surface heat dissipation structure in which the base substrates 60 are disposed on two surfaces of the electronic device 10 including the first and second devices stacked on each other are applied to the semiconductor package 100 according to the present embodiment. In addition, a heat transfer path formed of a material having high thermal conductivity may be provided between the electronic device 10 and the base substrates 60 and the base substrates 60 may be disposed directly on the external connection terminals 20, such that a distance between the electronic device 10 and the base substrates 60 may be significantly reduced.

Thus, significantly improved heat dissipation properties may be obtained as compared with a semiconductor package according to the related art, thereby ensuring a long-term reliability of the semiconductor package 100.

The semiconductor package 100 according to the present embodiment is configured in such a manner that the power semiconductor device 12 and the diode device 14 of the electronic device 10 are sequentially stacked rather being disposed on the same plane. Unlike a semiconductor package according to the related art, bonding wires and the like, for electrically connecting the electronic device 10 and the external connection terminals 20 to each other are not used in the semiconductor package 100 according to the present embodiment, and thus, the size of the semiconductor package 100 may be reduced.

Accordingly, an area for mounting devices may be minimized, and thus, the semiconductor package 100 may be used in various electronic devices that require miniaturization/high integration.

Furthermore, the semiconductor package module 1 according to the present embodiment may effectively dissipate heat generated from the semiconductor package 100 by using the heat dissipation member 90. Thus, semiconductor packages 100 that generate an excessive amount of heat may be modularized.

In addition, the semiconductor package module 1 according to the present embodiment may be configured in such a manner that each of the semiconductor packages 100 may be easily separated from the heat dissipation member 90. Thus, even if errors arise in a predetermined semiconductor package 100, only the predetermined semiconductor package 100 may be replaced with a new semiconductor package 100 without replacing the overall semiconductor package module 1 itself.

Thus, maintenance may be easily performed on the semiconductor package module 1 and costs against errors that arise in the semiconductor package module 1 may be minimized.

In the semiconductor package module 1 according to the present embodiment, as the semiconductor package 100 is inserted into the through hole 98 of the heat dissipation member 90 and is coupled to the heat dissipation member 90, four surfaces of the semiconductor package 100 may surface-contact the heat dissipation member 90.

That is, the semiconductor package 100 is formed such that the molding part 70, on which the base substrate 60 is not disposed, as well as the base substrate 60, may surface-contact the heat dissipation member 90.

Thus, both heat transferred from the electronic device 10 to the base substrate 60 and heat transferred through the molding part 70 may be transferred to the heat dissipation member 90 and may be dissipated outwardly, thereby significantly increasing a heat dissipation effect.

The heat dissipation member 90 according to the present embodiment is not limited to the above-described structure and various applications thereof may be used.

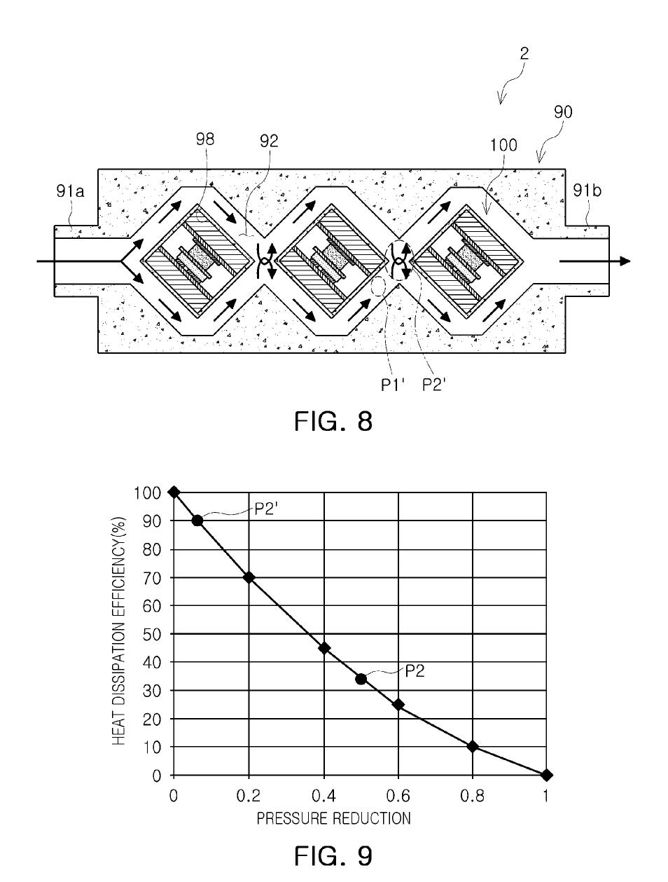

FIG. 8 is a schematic cross-sectional view of a semiconductor package module according to another embodiment of the present invention and corresponds to the semiconductor package module 1 taken along line C-D of FIG. 1.

The semiconductor package module according to the present embodiment has a similar structure to the above-described embodiment, except for through hole and flow channel structures. Thus, a repeated explanation regarding components the same as those of the above-described embodiment will not be given and the through hole and flow channel structures will be described in greater detail.

Referring to FIG. 8, in the heat dissipation member 90 of a semiconductor package module 2 according to the present embodiment, the through holes 98 are formed to have a diamond shapes. That is, two adjacent through holes 98 are disposed such that two corners of the two adjacent through holes 98 are most adjacent to each other. Likewise, the inlet 91a and the outlet 91b are respectively disposed adjacent to corners of the through hole 98.

Thus, the semiconductor packages 100 disposed within the through holes 98 may be arranged to have diamond shapes in which corners thereof are adjacent to each other.

As shown in FIG. 8, in the heat dissipation member 90 according to the present embodiment, an entire path of the flow channel 92 has a diamond pattern shape.

Accordingly, the refrigerant introduced into the flow channel 92 through the inlet 91a may be divided along the flow channel 92 having a diamond pattern shape, sequentially contact the overall side wall of the through hole 98, and move toward the outlet 91b.

The heat dissipation member 90 according to the present embodiment may allow the refrigerant to contact a maximum area of the side wall of the through hole 98 without any separate protrusion formed in the flow channel 92, unlike in the above-described embodiment of the present invention.

When the flow channel 92 has a diamond pattern shape, a heat dissipation effect may be further increased as compared with the above-described embodiment of the present invention.

FIG. 9 is a graph illustrating a relationship between a pressure reduction in a flow channel of the semiconductor package module according to the embodiment of the present invention and heat dissipation efficiency. With regard to the heat dissipation member 90 shown in FIGS. 6 and 8, when pressure in divided flow channels P1 and P1′ is 1,a flow channel cross-sectional area at intersections P2 and P2′ at which the divided flow channels P1 and P1′ are combined is increased, pressure in the intersections P2 and P2′ is reduced.

Through a simulation, in the case of the heat dissipation member 90 shown in FIG. 6, it was measured that pressure in the intersection P2 at which the divided flow channels P1 are combined is remarkably reduced, and accordingly, dissipation efficiency is lowered by about 35%.

However, in the case of the heat dissipation member 90 shown in FIG. 8, it was measured that pressure in the intersection P2′ at which the divided flow channels P1′ are combined is barely reduced, and thus, dissipation efficiency is maintained to about 90%.

Accordingly, it is confirmed that, when the heat dissipation member 90 according to the embodiments of the present invention is configured in such a manner that the flow channel 92 has a diamond pattern shape, a heat dissipation effect maybe further increased. However, the preset invention is not limited thereto. That is, the flow channel 92 may be formed in various forms as long as the flow channel 92 may significantly increase a heat dissipation effect.

The semiconductor package is not limited to the above-described embodiments of the present invention and various applications thereof may be used. For example, according to the embodiments of the present invention, the semiconductor package has a rectangular parallelepiped shape overall, but the present invention is not limited thereto. That is, the semiconductor package may have a cylindrical shape, a polyprism shape, or the like, as needed.

In addition, to the embodiments of the present invention exemplifies a power semiconductor package. However, the present invention is not limited thereto and an electronic component in which at least one electronic device is packaged may be applied to the present invention.

As set forth above, according to the embodiments of the present invention, the semiconductor package module may effectively dissipate heat generated from a semiconductor package by using a heat dissipation member. Thus, power semiconductor packages that generate an excessive amount of heat may be modularized.

Furthermore, the semiconductor packages may be easily separated from the heat dissipation member. That is, even if errors arise in a predetermined semiconductor package, only the predetermined semiconductor package may be replaced with a new semiconductor package without replacing the overall semiconductor package module itself. Thus, maintenance of the semiconductor package module maybe easily performed and costs against errors that arise in the semiconductor package module may be minimized.

In the semiconductor package module according to the above-described embodiments of the present embodiment, the semiconductor package is inserted into a through hole of the heat dissipation member and is coupled to the heat dissipation member, such that four surfaces of the semiconductor package may surface-contact the heat dissipation member. That is, the semiconductor package is formed such that a molding part, on which a base substrate is not disposed, as well as the base substrate may surface-contact the heat dissipation member.

Thus, both heat transferred from an electronic device to the base substrate and heat transferred through the molding part may be transferred to the heat dissipation member and may be dissipated outwardly, thereby significantly increasing a heat dissipation effect.

While the present invention has been shown and described in connection with the embodiments, it will be apparent to those skilled in the art that modifications and variations can be made without departing from the spirit and scope of the invention as defined by the appended claims.

1. A semiconductor package module, comprising:
a plurality of semiconductor packages; and
a heat dissipation member having a pipe shape including a flow channel formed therein and including a plurality of through holes into which the plurality of semiconductor packages are inserted, respectively,
wherein the plurality of through holes have shapes corresponding to those of the plurality of semiconductor packages,
wherein individual surfaces of the plurality of semiconductor packages surface-contact the heat dissipation member, and
wherein the heat dissipation member includes at least one protrusion protruding into the flow channel and guiding a flow of a refrigerant in the flow channel towards the semiconductor packages.

2. The semiconductor package module of claim 1, wherein the semiconductor packages each have a rectangular cross section and are inserted into the heat dissipation member so as to be arranged to be parallel to each other.

3. (canceled)

4. The semiconductor package module of claim 1, wherein the protrusion is disposed in a space formed between the through holes that are adjacent to each other in. the flow channel.

5-6. (canceled)

7. The semiconductor package module of claim 1, further comprising a substrate connected with external connection terminals of the semiconductor packages.

8. The semiconductor package module of claim 1, further comprising a bus bar electrically connected to all of common connection terminals among external connection terminals of the semiconductor packages.

9. The semiconductor package module of claim 1, wherein each of the semiconductor packages includes:
a common connection terminal having a flat plate shape;
first and second electronic devices respectively bonded to two surfaces of the common connection terminal;
first and second connection terminals each having a fiat plate shape and bonded to the first electronic device; and
a third connection terminal having a flat plate shape and bonded to the second electronic device.

10. The semiconductor package module of claim 9, wherein the first electronic device is a power semiconductor device, and the second electronic device is a diode device.

11. The semiconductor package module of claim 9, wherein the common connection terminal is a collector terminal, the first connection terminal is a gate terminal, the second connection terminal is an emitter terminal, and the third connection terminal is an anode terminal.

12. The semiconductor package module of claim 9, wherein the common connection terminal, the first connection terminal, the second connection terminal, and the third connection terminal are arranged to be parallel to each other.

13. The semiconductor package module of claim 9, wherein the first connection terminal, the second connection terminal, and the third connection terminal protrude toward one surface of each semiconductor package, and the common connection terminal protrudes toward the other surface thereof.

14. The semiconductor package module of claim 9, further comprising a base substrate for dissipating heat, disposed in at least one side of an exterior of the first, second, and third connection terminals.

15. The semiconductor package module of claim 14, wherein the semiconductor packages arc respectively formed in such a manner that at least one surface of the base substrate is coupled to the heat dissipation member so as to surface-contact the heat dissipation member.

16. The semiconductor package module of claim 9, further comprising a molding part for sealing the first and second electronic devices therein.

17. The semiconductor package module of claim 1, wherein the heat dissipation member further includes at least one support protrusion for supporting the semiconductor packages, the support protrusion being formed at either opening of both ends of the through holes.

18. A semiconductor package module comprising:
a heat dissipation member including a flow channel formed therein, the flow channel having a refrigerant flowing therein; and
at least one or more semiconductor packages detachably inserted into the heat dissipation member and having a rectangular parallelepiped shape,
wherein the at least one or more semiconductor packages each have at least four surfaces surface-contacting the heat dissipation member, and
wherein the heat dissipation member includes at least one protrusion protruding into the flow channel and guiding a flow of a refrigerant in the flow channel towards the at least one or more semiconductor packages.

19. (canceled)

20. The semiconductor package module of claim 1, wherein the plurality of semiconductor packages each have at least four of the individual surfaces.
